(19) United States
(12) Patent Application Publication
(10) Pub. No.: US 2021/0055751 A1
(43) Pub. Date: Feb. 25, 2021

(54) DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xia CHEN, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 16/763,056

(22) PCT Filed: Nov. 20, 2019
(86) PCT No.: PCT/CN2019/119712

§ 371 Date: May 11, 2020

(30) Foreign Application Priority Data
Aug. 19, 2019 (CN) 201910765484.1

(51) Int. Cl. G05D 23/19; G05B 15/02; H05K 5/00; H05K 5/02; G01P 3/00

(52) U.S. Cl. CPC G05D 23/1928; G05B 15/02; G01P 3/00; H05K 5/0217; H05K 5/0017

(57) ABSTRACT

A display device is provided. The display device includes a speed sensor, a control module, an adjustment module, and a posture detection module. The speed sensor is for detecting a real-time speed during a falling process of the display device. The control module is configured for controlling an adjustment module to perform an adjustment operation according to the real-time speed. The adjustment module is configured for adjusting a posture of the display device during the falling process, so that a part of the display device that is not used for display is in contact with the ground. The posture detection module configured to detect a real-time posture during the falling process of the display device, and feeding real-time posture information back to the control module.

### FIELD OF INVENTION

This disclosure relates to a field of display technology, and more particularly, to a display device.

### BACKGROUND OF INVENTION

In a conventional flexible organic light emitting diode display device, when the display device falls down, since a cover plate, optical glue, touch layer and a polarizer disposed on a display layer of the organic light emitting diode display device are all flexible materials, the force impact dispersion effect is poor, easily causing too large local stress, and failure of the display device.

### SUMMARY OF INVENTION

An embodiment of the disclosure provides a display device to solve a technical problem that a display panel is ineffective since the force dispersion effect of a partial structure of the display panel is poor when the conventional display device falls down.

The disclosure provides a display device, which comprises:

a speed sensor configured for detecting a real-time speed during a falling process of the display device, and for feeding the real-time speed back to a control module;

the control module configured for controlling an adjustment module to perform an adjustment operation according to the real-time speed;

the adjustment module configured for adjusting a posture of the display device during the falling process so that a part of the display device that is not used for display is in contact with the ground; and

a posture detection module configured for detecting a real-time posture during the falling process of the display device, and feeding real-time posture information back to the control module;

wherein the control module is electrically connected to the speed sensor, the adjustment module and the posture detection module, respectively;

wherein the control module includes:

a first comparison unit configured to compare the real-time speed with a predetermined speed, and to feed a comparison result back to a control unit;

a second comparison unit configured to compare the real-time posture and a predetermined posture, and to feed a comparison result back to the control unit; and

the control unit is configured to control the adjustment module to start the adjustment operation when the real-time speed is greater than or equal to the predetermined speed, and to control the adjustment module to stop the adjustment operation when the real-time posture is the same as the predetermined posture;

wherein the first comparison unit and the second comparison unit are electrically connected to the control unit, respectively;

wherein the display device comprises a receiving recess, and an opening of the receiving recess is disposed in an edge region of the display device facing a user, and the adjustment module is disposed in the receiving recess.

In the display device of the disclosure, the adjustment module comprises: a fan blade for adjusting the posture of the display device in the air; and a first driving element configured to drive the fan blade to rotate, and a rotating shaft of the first driving element is fixedly connected to the fan blade.

In the display device of the disclosure, the adjustment module comprises: a parachute for adjusting the posture of the display device in the air; a fixing plate fixedly connected to a parachute rope of the parachute; and a first driving element, wherein a push rod of the first driving element is fixedly connected to the fixing plate.

In the display device of the disclosure, the adjustment module further comprises a slide rail, the slide rail is disposed on an opposite side of a recess wall of the receiving recess, a sliding port slidingly matched with the slide rail is disposed on an opposite side of the fixing plate, the slide rail extends into the sliding port, and the fixing plate slides along a extending direction of the slide rail.

In the display device of the disclosure, the adjustment module further comprises a limiting block, the limiting block is disposed at an end of the slide rail near the opening for limiting the fixing plate.

In the display device of the disclosure, the first driving element is an automatic ejection device.

In the display device of the disclosure, the adjustment module further comprises a sealing cover and a second driving element, the sealing cover is disposed above the receiving recess, the sealing cover is configured to seal the receiving recess, and the second driving element is configured to drive the sealing cover to seal and open the receiving recess.

In the display device of the disclosure, the predetermined posture comprises a vertical state and a back-down state.

The disclosure further provides a display device, which comprises:

a speed sensor configured for detecting a real-time speed during a falling process of the display device, and for feeding the real-time speed back to a control module;

the control module configured for controlling an adjustment module to perform an adjustment operation according to the real-time speed;

the adjustment module configured for adjusting a posture of the display device during the falling process so that a part of the display device that is not used for display is in contact with the ground; and

a posture detection module configured for detecting a real-time posture during the falling process of the display device, and feeding real-time posture information back to the control module;

wherein the control module is electrically connected to the speed sensor, the adjustment module and the posture detection module, respectively.

In the display device of the disclosure, the control module includes:

a first comparison unit configured to compare the real-time speed with a predetermined speed, and to feed a comparison result back to a control unit;

a second comparison unit configured to compare the real-time posture and the predetermined posture, and to feed a comparison result back to the control unit; and

the control unit is configured to control the adjustment module to start the adjustment operation when the real-time speed is greater than or equal to the predetermined speed, and control the adjustment module to stop the adjustment operation when the real-time posture is the same as the predetermined posture;

wherein the first comparison unit and the second comparison unit are electrically connected to the control unit, respectively.

In the display device of the disclosure, the display device comprises a receiving recess, and an opening of the receiving recess is disposed in an edge region of the display device facing a user, and the adjustment module is disposed in the receiving recess.

In a first embodiment of the display device of the disclosure, the adjustment module comprises: a fan blade for adjusting the posture of the display device in the air; and a first driving element configured to drive the fan blade to rotate, and a rotating shaft of the first driving element is fixedly connected to the fan blade.

In the first embodiment of the display device of the disclosure, the first driving element is a driving motor.

In the first embodiment of the display device of the disclosure, the number of the adjustment modules is four, and the four adjustment modules are disposed in four corner regions of the display device.

In a second embodiment of the display device of the disclosure, the adjustment module comprises: a parachute for adjusting the posture of the display device in the air; a fixing plate fixedly connected to a parachute rope of the parachute; and a first driving element, wherein a push rod of the first driving element is fixedly connected to the fixing plate.

In the display device of the disclosure, the adjustment module further comprises a slide rail, the slide rail is disposed on an opposite side of a recess wall of the receiving recess, a sliding port slidingly matched with the slide rail is disposed on an opposite side of the fixing plate, the slide rail extends into the sliding port, and the fixing plate slides along a extending direction of the slide rail.

In the second embodiment of the display device of the disclosure, the adjustment module further comprises a limiting block, the limiting block is disposed at an end of the slide rail near the opening for limiting the fixing plate.

In the second embodiment of the display device of the disclosure, the first driving element is an automatic ejection device.

In the display device of the disclosure, the adjustment module further comprises a sealing cover and a second driving element, the sealing cover is disposed above the receiving recess, the sealing cover is configured to seal the receiving recess, and the second driving element is configured to drive the sealing cover to seal and open the receiving recess.

In the second embodiment of the display device of the disclosure, the number of the adjustment modules is four, and the four adjustment modules are disposed in four corner regions of the display device.

In the display device of the disclosure, the predetermined posture comprises a vertical state and a back-down state.

Advantageous effects of the disclosure are as follows. The disclosure provides a display device. Compared with the conventional display device, the display device of the disclosure detects the real-time speed of the display device during the falling process through a speed sensor, and transfers real-time speed information to the control module. When the real-time speed reaches the predetermined speed, the control module controls the adjustment module to adjust the posture of the display device in the air, so that the display device contacts the ground in the predetermined posture for preventing the contact between a display surface of the display device and the ground. That solves the technical problem that the display panel is ineffective since the force impact dispersion effect of a partial structure of the display panel is poor when the conventional display device falls down.

### DESCRIPTION OF DRAWINGS

In order to more clearly illustrate the embodiments of the disclosure or the technical solutions in the prior art, the following briefly introduces the accompanying drawings used in the embodiments. Obviously, the drawings in the following description merely show some of the embodiments of the disclosure. As regards one of ordinary skill in the art, other drawings can be obtained in accordance with these accompanying drawings without making creative efforts.

FIG. 1 is a structural schematic diagram of a display device in a first embodiment of the disclosure.

FIG. 2 is a top view schematic diagram of a display device in the first embodiment of the disclosure.

FIG. 3 is a structural schematic diagram of an adjustment module and a surrounding structure of the display device according to the first embodiment of the disclosure.

FIG. 4 is a structural schematic diagram of an adjustment module and a surrounding structure of the display device according to a second embodiment of the disclosure.

### DETAILED DESCRIPTION OF PREFERRED EMBODIMENTS

Referring to the drawings of the disclosure, similar components are labeled with the same number. This description of the exemplary embodiments is intended to be read in connection with the accompanying drawings, which are to be considered part of the entire written description, and should not be deemed to limit other specific embodiments not detailed herein in this disclosure.

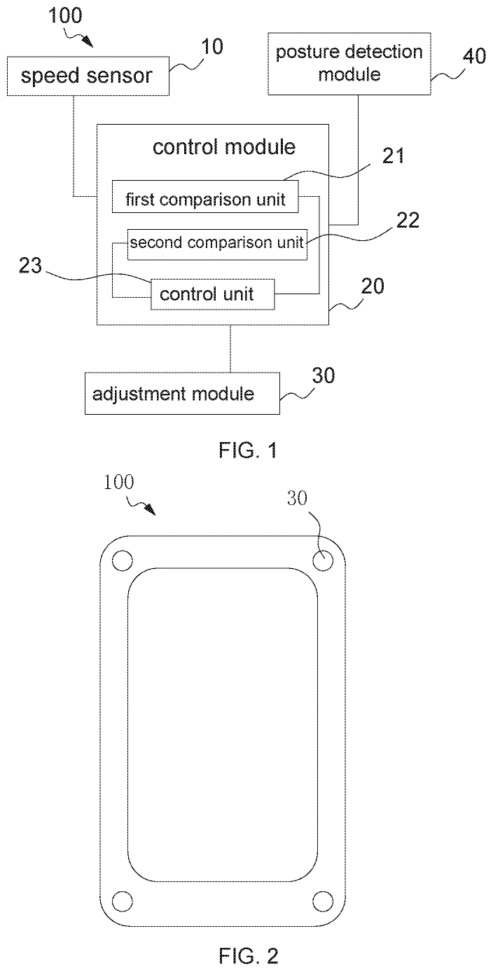

Referring to FIG. 1 and FIG. 2, a structural schematic diagram of a display device in a first embodiment of the disclosure and a top view schematic diagram of a display device in the first embodiment of the disclosure are shown.

It should be noted that the display device of the disclosure is a display product such as a mobile phone or a tablet.

The display device 100 according to the first embodiment of the disclosure includes a speed sensor 10, a control module 20, an adjustment module 30, and an posture detection module 40.

The speed sensor 10 is configured for detecting a real-time speed during a falling process of the display device 100, and for feeding the real-time speed back to a control module 20.

The control module 20 is configured to control the adjustment module 30 to perform an adjustment operation according to the real-time speed.

The adjustment module 30 is configured to adjust a posture of the display device 100 during the falling process, so that a part of the display device 100 that is not used for display is in contact with the ground.

The posture detection module 40 is configured to detect a real-time posture during the falling process of the display device 100 and to feed real-time posture information back to the control module 20.

The control module 20 is electrically connected to the speed sensor 10, the adjustment module 30 and the posture detection module 40, respectively.

The display device 100 of the first embodiment detects the real-time speed of the display device 100 during the falling process through the speed sensor 10 and transmits the real-time speed information to the control module 20. When the real-time speed reaches a predetermined speed, the control module 20 controls the adjustment module 30 to adjust the posture of the display device 100 in the air, so that the display device 100 is in contact with the ground in a predetermined posture, and prevents a display surface of the display device 100 from contacting the ground.

Specifically, the control module 20 includes a first comparison unit 21, a second comparison unit 22, and a control unit 23. The first comparison unit 21 and the second comparison unit 22 are electrically connected to the control unit 23, respectively.

The first comparison unit 21 is configured to compare the real-time speed with a predetermined speed, and to feed a comparison result back to the control unit.

The second comparison unit 22 is configured to compare the real-time posture and a predetermined posture, and to feed a comparison result back to the control unit 23.

The control unit 23 is configured to control the adjustment module 30 to start an adjustment operation when the real-time speed is greater than or equal to the predetermined speed, and to control the adjustment module 30 to stop the adjustment operation when the real-time attitude is the same as the predetermined posture.

The predetermined speed can be set according to the actual situation, which is not limited in this disclosure.

The predetermined posture includes a vertical state and a back surface-down state. The vertical state in this disclosure should be considered as a substantially vertical state. A certain error may occur to the vertical state under the actual condition, so the vertical state should be based upon the conventional understanding of those skilled in the art. A back surface here is relative to the display surface of the display device. That is, in the display device, the display surface (used to display) is a front surface, and a surface facing away from the display surface is the back surface.

The portions of the display device 100 without a display function include edge portions, corner portions, and an outer casing of the display device 100. In the vertical state, the edge portions or the corner portions of the display device 100 first contact the ground. In the back-down state, the outer casing of the display device 100 first contacts the ground.

In the first embodiment of the display device 100, the display device 100 includes a receiving recess 50. A opening of the receiving recess 50 is disposed in an edge region of the display device facing a user, and the adjustment module 30 is disposed in the receiving recess 50.

There are at least two adjustment devices 30, and the adjustment devices 30 are disposed opposite each other. In the first embodiment, the number of the adjustment modules 30 is four, but it is not limited thereto. The four adjustment modules 30 are disposed in four corner regions of the display device 100.

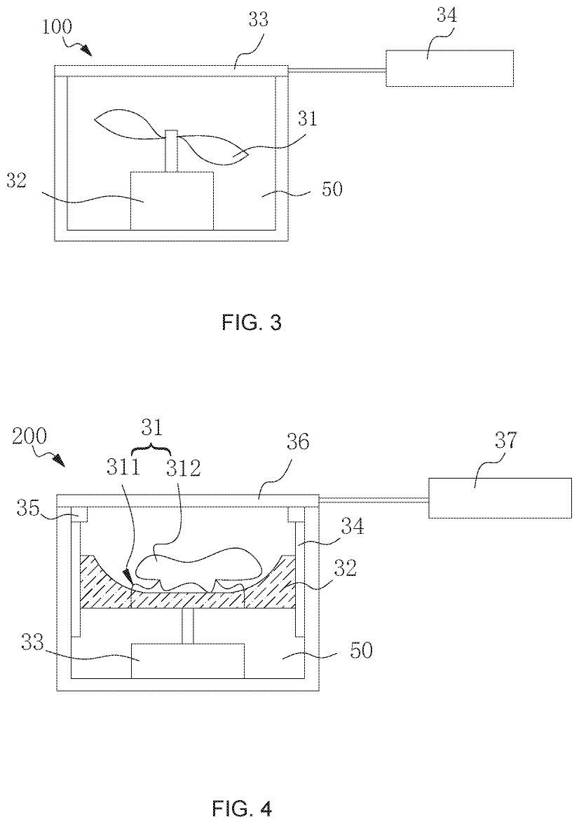

Referring to FIG. 3, the adjustment module 30 includes a fan blade 31 and a first driving element 32.

The fan blade 31 is configured to adjust the posture of the display device 100 in the air. The first driving element 32 is used to drive the fan blade 31 to rotate. A rotating shaft of the first driving element 32 is fixedly connected to the fan blade 31. The first driving element 32 is a driving motor.

The adjustment module 30 further includes a sealing cover 33 and a second driving element 34. The sealing cover 33 is disposed above the receiving recess 50. The sealing cover 33 is configured to seal the receiving recess 50. The second driving element 34 is configured to drive the sealing cover 33 to seal and open the receiving recess 50.

When the adjustment module 30 is activated, the second driving element 34 is activated first. The second driving element 34 pulls the sealing cover 33, and the sealing cover 33 is away from the opening of the receiving recess 50. Then, the first driving element 32 is activated, and the first driving element 32 drives the fan blade 31 to rotate. When the adjustment module 30 is turned off, the first driving element 31 is stopped first, and then the second driving element 34 is activated to push the sealing cover 33 to cover the opening of the receiving recess 50. Optionally, the second driving element 34 is an automatic telescopic device.

When the adjustment module 30 receives a start signal sent by the control module 20, the first driving element 32 drives the fan blade 31 to rotate. The fan blade 31 pushes air during the rotation, and the air will react to the fan blade 31, so that the display device 100 integrated with the fan blade 31 will flip under the reverse action of air.

Of course, during the falling process of the display device 100, the control module 20 controls whether each adjustment module 30 is turned on and a rotation speed of a first driving element 32 (driving motor) of a turned-on adjustment module 30 according to the real-time posture of the display device 100, so as to make the display device 100 reach the predetermined posture.

When the display device 100 falls down, the operation process of the first embodiment is described as follow.

The speed sensor 10 monitors the falling speed of the display device 100 in real time, and feeds the real-time speed information back to the control module 20.

The first comparison unit 21 of the control module 20 compares the real-time speed transmitted from the speed sensor 10 with the predetermined speed, and transmits the comparison result to the control unit 23. When the real-time speed is greater than or equal to the predetermined speed, the control unit 23 acquires a current posture of the display device 100, and controls a turned on/turned off condition of each adjustment module 30 and a rotation speed of the first driving element 32 according to the current posture, so that the posture of the display device 100 is maintained the same as the predetermined posture.

Besides, the current posture information of the display device 100 acquired by the control unit 23 is obtained through sensing by the posture detection module 40.

When the posture detection module 40 detects the real-time posture of the display device 100 and transmits it to the second comparison unit 22, the second comparison unit 22 compares the real-time posture of the display device 100 with the predetermined posture, and feeds the comparison result back to the control unit 23. When the real-time posture is the same as the predetermined posture, the control unit 23 controls the adjustment module 30 to turn off.

Referring to FIG. 4, in the second embodiment of the display device 200 according to the disclosure, the sealing cover 36 is disposed on the opening of the receiving recess 50, and the second driving element 37 is configured to drive the sealing cover 36 to close and open the opening. The second embodiment of the disclosure is structurally different from the first embodiment in the following description.

The adjustment module 30 comprises a parachute 31, a fixing plate 32, first driving element 33, a slide rail 34, and a limiting block.

The parachute 31 is configured for adjusting the posture of the display device in the air. After the parachute 31 is deployed in the air, not only the posture of the display device 200 in the air can be adjusted, but also the falling speed of the display device 200 in the air can be reduced, and the collision force between the display device 200 and the ground can be further reduced. The parachute 31 includes a rope 311 and a body 312 connected to the umbrella rope 311.

The fixing plate 32 is fixedly connected to the umbrella rope of the parachute 31.

The push rod of the first driving element 33 is fixedly connected to the fixing plate 32. Optionally, the first driving element 33 is an automatic ejection device or an automatic telescopic device.

The slide rails 34 are disposed on opposite sides of recess walls of the receiving recess 50, sliding ports slidingly matched with the slide rails are disposed on opposite sides of the fixing plate 32, the slide rails 34 extend into the sliding ports, so that the fixing plate 32 slides along a extending direction of the slide rails 34.

The limiting block 35 is disposed at an end of the slide rail 34 near the opening of the receiving recess 50, and is configured for limiting the fixing plate. On the one hand, the effect of the limiting block 35 is to prevent the fixing plate 32 from exceeding the receiving recess 50. On the other hand, the effect of the limiting block 35 is to prevent the fixing plate 32 from detaching from the holding recess 50 under the pulling force of the parachute 31 when the parachute 31 is ejected and opened.

In a second embodiment of the display device of the disclosure, the number of the adjustment modules is four, and the four adjustment modules are disposed in four corner regions of the display device.

When the display device 200 falls down, the operation process of the second embodiment is described as follow.

The speed sensor 10 monitors the falling speed of the display device 200 in real time, and feeds the real-time speed information back to the control module 20.

The first comparison unit 21 of the control module 20 compares the real-time speed transmitted from the speed sensor 10 with the predetermined speed, and transmits the comparison result to the control unit 23. When the real-time speed is greater than or equal to the predetermined speed, the control unit 23 acquires a current posture of the display device 200, and controls a turned on/turned off condition of each adjustment module 30 according to the current posture, so that the posture of the display device 100 is maintained the same as the predetermined posture.

Besides, the current posture information of the display device 200 acquired by the control unit 23 is obtained through sensing by the posture detection module 40.

When the posture detection module 40 detects the real-time posture of the display device 200 and transmits it to the second comparison unit 22, the second comparison unit 22 compares the real-time posture of the display device 200 with the predetermined posture, and feeds the comparison result back to the control unit 23. When the real-time posture is the same as the predetermined posture, the control unit 23 controls the adjustment module 30 to turn off.

For example, the display device 200 turns on two adjustment modules 30 on the same side, and the parachutes 31 of the two adjustment modules 30 are ejected by the first driving element 33 and deployed in the air, so that the display device 200 can be in a vertical state. If all of the four adjustment modules 30 are turned on, the display device 200 is in a state of the back surface facing downward.

The disclosure provides a display device. Compared with the conventional display device, the display device of the disclosure detects the real-time speed of the display device during the falling process through a speed sensor, and transfers real-time speed information to the control module. When the real-time speed reaches the predetermined speed, the control module controls the adjustment module to adjust the posture of the display device in the air, so that the display device contacts the ground in the predetermined posture for preventing the contact between a display surface of the display device and the ground. That solves the technical problem that the display panel is ineffective since the force impact dispersion effect of a partial structure of the display panel is poor when the conventional display device falls down.

This disclosure has been described with preferred embodiments thereof, and it is understood that many changes and modifications to the described embodiment can be carried out without departing from the scope and the spirit of the invention that is intended to be limited only by the appended claims.

What is claimed is:

1. A display device, comprising:
a speed sensor configured for detecting a real-time speed during a falling process of the display device, and for feeding the real-time speed back to a control module;
the control module configured for controlling an adjustment module to perform an adjustment operation according to the real-time speed;
the adjustment module configured for adjusting a posture of the display device during the falling process so that a part of the display device that is not used for display is in contact with the ground; and
a posture detection module configured for detecting a real-time posture during the falling process of the display device, and feeding real-time posture information back to the control module;
wherein the control module is electrically connected to the speed sensor, the adjustment module and the posture detection module, respectively;
wherein the control module includes:
a first comparison unit configured to compare the real-time speed with a predetermined speed, and to feed a comparison result back to a control unit;
a second comparison unit configured to compare the real-time posture and a predetermined posture, and to feed a comparison result back to the control unit; and
the control unit is configured to control the adjustment module to start the adjustment operation when the real-time speed is greater than or equal to the predetermined speed, and to control the adjustment module to stop the adjustment operation when the real-time posture is the same as the predetermined posture;
wherein the first comparison unit and the second comparison unit are electrically connected to the control unit, respectively;
wherein the display device comprises a receiving recess, and a opening of the receiving recess is disposed in an edge region of the display device facing a user, and the adjustment module is disposed in the receiving recess.

2. The display device according to claim 1, wherein the adjustment module comprises:
a fan blade for adjusting the posture of the display device in the air; and
a first driving element configured to drive the fan blade to rotate, and a rotating shaft of the first driving element is fixedly connected to the fan blade.

3. The display device according to claim 1, wherein the adjustment module comprises:
a parachute for adjusting the posture of the display device in the air;
a fixing plate fixedly connected to a parachute rope of the parachute; and
a first driving element, wherein a push rod of the first driving element is fixedly connected to the fixing plate.

4. The display device according to claim 3, wherein the adjustment module further comprises a slide rail, the slide rail is disposed on an opposite side of a recess wall of the receiving recess, a sliding port slidingly matched with the slide rail is disposed on an opposite side of the fixing plate, the slide rail extends into the sliding port, and the fixing plate slides along a extending direction of the slide rail.

5. The display device according to claim 4, wherein the adjustment module further comprises a limiting block, the limiting block is disposed at an end of the slide rail near the opening for limiting the fixing plate.

6. The display device according to claim 3, wherein the first driving element is an automatic ejection device.

7. The display device according to claim 2, wherein the adjustment module further comprises a sealing cover and a second driving element, the sealing cover is disposed above the receiving recess, the sealing cover is configured to seal the receiving recess, and the second driving element is configured to drive the sealing cover to seal and open the receiving recess.

8. The display device according to claim 1, wherein the predetermined posture comprises a vertical state and a back-down state.

9. A display device, comprising:
a speed sensor configured for detecting a real-time speed during a falling process of the display device, and for feeding the real-time speed back to a control module;
the control module configured for controlling an adjustment module to perform an adjustment operation according to the real-time speed;
the adjustment module configured for adjusting a posture of the display device during the falling process, so that a part of the display device that is not used for display is in contact with the ground; and
a posture detection module configured for detecting a real-time posture during the falling process of the display device, and to feed real-time posture information back to the control module;
wherein the control module is electrically connected to the speed sensor, the adjustment module and the posture detection module, respectively.

10. The display device according to claim 9, wherein the control module includes:
a first comparison unit configured to compare the real-time speed with a predetermined speed, and to feed a comparison result back to a control unit;
a second comparison unit configured to compare the real-time posture and a predetermined posture, and to feed a comparison result back to the control unit; and
the control unit is configured to control the adjustment module to start the adjustment operation when the real-time speed is greater than or equal to the predetermined speed, and to control the adjustment module to stop the adjustment operation when the real-time posture is the same as the predetermined posture;
wherein the first comparison unit and the second comparison unit are electrically connected to the control unit, respectively.

11. The display device according to claim 9, wherein the display device comprises a receiving recess, and a opening of the receiving recess is disposed in an edge region of the display device facing a user, and the adjustment module is disposed in the receiving recess.

12. The display device according to claim 11, wherein the adjustment module comprises:
a fan blade for adjusting the posture of the display device in the air; and
a first driving element configured to drive the fan blade to rotate, and a rotating shaft of the first driving element is fixedly connected to the fan blade.

13. The display device according to claim 11, wherein the adjustment module comprises:
a parachute for adjusting the posture of the display device in the air;
a fixing plate fixedly connected to a parachute rope of the parachute; and
a first driving element, wherein a push rod of the first driving element is fixedly connected to the fixing plate.

14. The display device according to claim 13, wherein the adjustment module further comprises a slide rail, the slide rail is disposed on an opposite side of a recess wall of the receiving recess, a sliding port slidingly matched with the slide rail is disposed on an opposite side of the fixing plate, the slide rail extends into the sliding port, and the fixing plate slides along a extending direction of the slide rail.

15. The display device according to claim 14, wherein the adjustment module further comprises a limiting block, the limiting block is disposed at an end of the slide rail near the opening for limiting the fixing plate.

16. The display device according to claim 13, wherein the first driving element is an automatic ejection device.

17. The display device according to claim 13, wherein the adjustment module further comprises a sealing cover and a second driving element, the sealing cover is disposed above the receiving recess, the sealing cover is configured to seal the receiving recess, and the second driving element is configured to drive the sealing cover to seal and open the receiving recess.

18. The display device according to claim 10, wherein the predetermined posture comprises a vertical state and a back-down state.
